(19) United States
(12) Patent Application Publication
(10) Pub. No.: US 2024/0162196 A1
(43) Pub. Date: May 16, 2024

(54) POWER SEMICONDUCTOR DEVICE

(71) Applicant: Mitsubishi Electric Corporation, Tokyo (JP)

(72) Inventors: Rui KONISHI, Tokyo (JP); Naoki YOSHIMATSU, Tokyo (JP); Shintaro ARAKI, Tokyo (JP)

(73) Assignee: Mitsubishi Electric Corporation, Tokyo (JP)

(21) Appl. No.: 18/549,166

(22) PCT Filed: Apr. 20, 2021
(86) PCT No.: PCT/JP2021/016000

§ 371 Date: Sep. 5, 2023

(51) Int. Cl. H01L 25/065; H01L 23/00; H01L 23/495

(52) U.S. Cl. CPC H01L 25/0657; H01L 23/4952; H01L 23/49548; H01L 24/32; H01L 24/48; H01L 24/73; H01L 2224/32145; H01L 2224/48175; H01L 2224/48639; H01L 2224/73265; H01L 2225/06524; H01L 2924/13055

(57) ABSTRACT

A power semiconductor device includes a power semiconductor chip being a chip of a power semiconductor element, a temperature sensing diode chip being a chip of a temperature sensing diode element mounted in a first region on a surface electrode being one of main electrodes of the power semiconductor chip, and a lead frame connected to a second region on the surface electrode. An insulating film is provided on a side surface of the lead frame facing the temperature sensing diode chip.

### TECHNICAL FIELD

The present disclosure relates to a power semiconductor device, and more particularly to a power semiconductor device including a temperature sensing diode.

### BACKGROUND ART

For example, as a power semiconductor device used in an inverter for controlling a motor of an electric vehicle and an electric train, a converter for power regeneration, and the like, there is a known device that includes a temperature sensing diode for measuring the temperature of a power semiconductor element. For example, Patent Document 1 below discloses a power semiconductor device in which a chip of a temperature sensing diode is mounted on a surface electrode of a power semiconductor element together with a lead frame.

### PRIOR ART DOCUMENTS

### Patent Document(s)

[Patent Document 1] Japanese Patent Application Laid-Open No. 2019-186510

### SUMMARY

### Problem to be Solved by the Invention

When mounting a temperature sensing diode chip together with a lead frame on a surface electrode of a power semiconductor element, a problem lies in ensuring reliability of insulation between the lead frame and the temperature sensing diode.

The present disclosure has been made to solve the problem, and an object thereof is to improve the reliability of insulation between the lead frame and the temperature sensing diode mounted on the surface electrode of the power semiconductor device.

### Means to Solve the Problem

A power semiconductor device according to the present disclosure includes a power semiconductor chip being a chip of a power semiconductor element, a temperature sensing diode chip being a chip of a temperature sensing diode element mounted in a first region on a surface electrode being one of main electrodes of the power semiconductor chip, a lead frame connected to a second region on the surface electrode, and an insulating film provided on a side surface of the lead frame facing the temperature sensing diode chip.

### Effects of the Invention

According to the present disclosure, providing the insulating film on the side surfaces of the lead frame facing the temperature sensing diode chip improves the reliability of insulation between the lead frame and the temperature sensing diode chip.

The objects, features, aspects, and advantages of the present disclosure will become more apparent from the following detailed description and the accompanying drawings.

### BRIEF DESCRIPTION OF DRAWINGS

FIG. 1 A top view of a power semiconductor device according to Embodiment 1.

FIG. 2 A side view of the power semiconductor device according to Embodiment 1.

FIG. 3 A top view of an essential part of the power semiconductor device according to Embodiment 1.

FIG. 4 A cross-sectional view of the essential part of the power semiconductor device according to Embodiment 1.

FIG. 5 A top view of the essential part of the power semiconductor device according to Embodiment 1.

FIG. 6 A top view of an essential part of a power semiconductor device according to Embodiment 2.

FIG. 7 A top view of the essential part of the power semiconductor device according to Embodiment 2.

FIG. 8 A top view of an essential part of a power semiconductor device according to Embodiment 3.

FIG. 9 A top view of an essential part of a power semiconductor device according to Embodiment 4.

FIG. 10 A top view of an essential part of the power semiconductor device according to Embodiment 4.

FIG. 11 A cross-sectional view of an essential part of a power semiconductor device according to Embodiment 5.

FIG. 12 A cross-sectional view of the essential part of the power semiconductor device according to Embodiment 5.

FIG. 13 A cross-sectional view of the essential part of the power semiconductor device according to Embodiment 5.

FIG. 14 A cross-sectional view of an essential part of a power semiconductor device according to Embodiment 6.

### DESCRIPTION OF EMBODIMENT(S)

### Embodiment 1

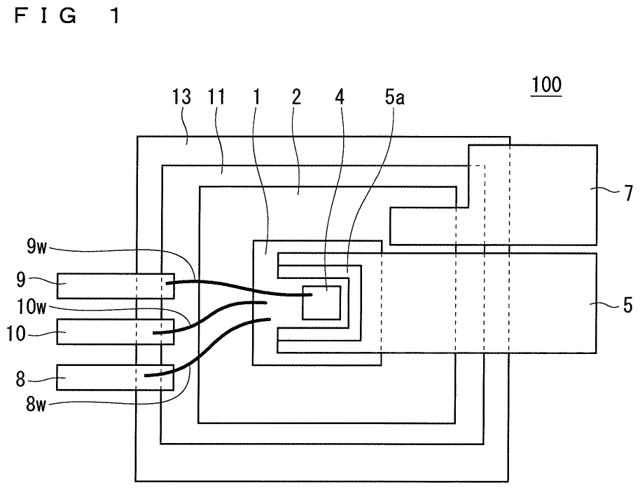

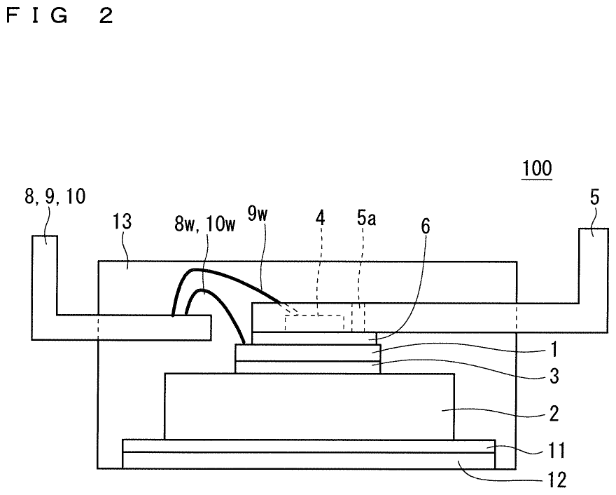

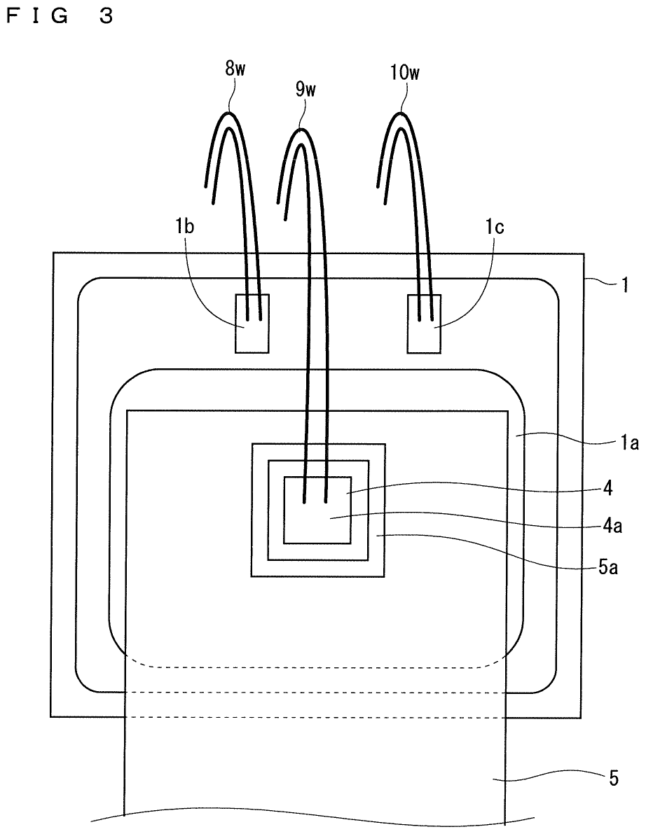

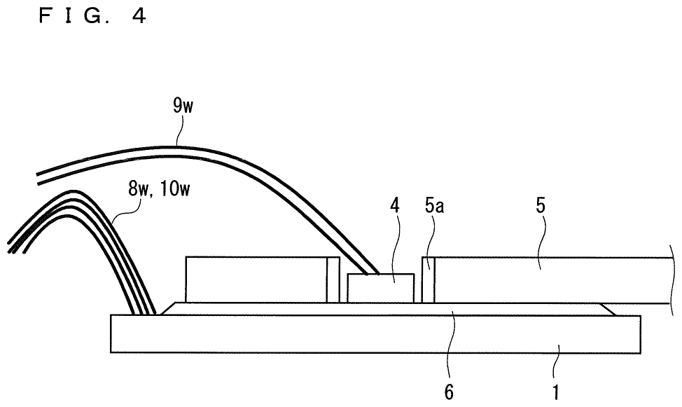

FIGS. 1 and 2 are a top view and a side view of a power semiconductor device 100 according to Embodiment 1. FIGS. 1 and 2 illustrate the front surface of the power semiconductor device 100 through a mold resin 20 that covers thereof in a transparent manner (the mold resin 20 is illustrated only in the outline thereof). Also, FIGS. 3 and 4 are a top view and a cross-sectional view of an essential part of the power semiconductor device 100 (in the vicinity of a power semiconductor chip 1).

As illustrated in FIGS. 1 and 2, in the power semiconductor device 100, the power semiconductor chip 1, which is a chip of a power semiconductor element, is mounted on a heat spreader 2. That is, the lower surface of the power semiconductor chip 1 is bonded to the upper surface of the heat spreader 2 using a bonding member 3 such as solder.

As illustrated in FIG. 3, a surface electrode 1a, which is one of main electrodes, is formed on the upper surface of the power semiconductor chip 1, and a temperature sensing diode chip 4, which is a chip of a temperature sensing diode element, and a lead frame 5 are mounted on the surface electrode 1a. As illustrated in FIG. 2, the lower surfaces of the temperature sensing diode chip 4 and the lead frame 5 are bonded to the upper surface of the surface electrode 1a using a bonding member 6.

In the surface electrode 1a, assuming the region where the temperature sensing diode chip 4 is mounted is a first region, and the region where the lead frame 5 is connected is a second region, the first region is defined in the central portion of the surface electrode 1a, and the second region is defined outside the surface electrode 1a in Embodiments. Further, as illustrated in FIGS. 3 and 4, the lead frame 5 has an opening at a portion corresponding to the first region, and the temperature sensing diode chip 4 is arranged in the opening of the lead frame 5. The dimensions of the opening are preferably slightly larger than the external dimensions of the temperature sensing diode chip 4 (approximately 0.2 mm to 2 mm).

Here, the side surfaces of the lead frame 5 facing the temperature sensing diode chip 4, that is, the side walls of the opening of the lead frame 5 are coated with an insulating film 5a made of, for example, a resin. By providing the insulating film 5a on the side surfaces of the lead frame 5 facing the temperature sensing diode chip 4, the effect is obtained that the reliability of insulation between the lead frame 5 and the temperature sensing diode chip 4 is improved.

The power semiconductor chip 1 may be any element such as an Insulated Gate Bipolar Transistor (IGBT), a Metal-Oxide-Semiconductor Field Effect Transistor (MOSFET), a Schottky barrier diode, an PN junction diode or the like. Here, it is assumed that the power semiconductor chip 1 is an IGBT. Specifically, the surface electrode 1a on the upper surface of the power semiconductor chip 1 is an emitter electrode, and the lead frame 5 connected thereto is an emitter terminal of the power semiconductor device 100. A collector electrode (not illustrated) is formed on the lower surface of the power semiconductor chip 1, and the collector electrode is electrically connected to the heat spreader 2 made of conductive metal or the like through the bonding member 3. Therefore, in Embodiment 1, a lead frame 7 serving as the emitter terminal of the power semiconductor device 100 is bonded to the heat spreader 2 as illustrated in FIG. 1. Further, as illustrated in FIG. 3, a gate pad 1b connected to the gate electrode of the IGBT is provided on the upper surface of the power semiconductor chip 1, and the gate pad 1b is connected to a gate terminal 8 (FIG. 1) of the power semiconductor device 100 through a gate wire 8w (for example, an aluminum wire) that is a wire for applying gate voltage.

Further, in Embodiment 1, the temperature sensing diode chip 4 has an anode electrode 4a on the upper surface thereof and a cathode electrode (not illustrated) on the lower surface thereof. The anode electrode 4a of the temperature sensing diode chip 4 is connected to an anode terminal 9 (FIG. 1) of the power semiconductor device 100 through an anode wire 9w (for example, an aluminum wire) which is a wire for voltage measurement of the anode electrode. A cathode electrode of the temperature sensing diode chip 4 is connected to the surface electrode 1a of the power semiconductor chip 1 through the bonding member 6. As illustrated in FIG. 3, a cathode pad 1c electrically connected to the surface electrode 1a is further provided on the upper surface of the power semiconductor chip 1, and the cathode pad 1c is connected to a cathode terminal 10 (FIG. 1) of the power semiconductor device 100 through a cathode wire 10w (for example, an aluminum wire) which is a wire for voltage measurement of the cathode electrode.

Through an insulating sheet 11, a metal foil 12, which enhances the heat dissipation of the heat spreader 2, is provided on the lower surface of the heat spreader 2.

The power semiconductor device 100 is configured by sealing the above elements with a mold resin 13. However, portions of the lead frame 5, the lead frame 7, the gate terminal 8, the anode terminal 9 and the cathode terminal 10, and the lower surface of the metal foil 12 are exposed from the mold resin 13.

Next, main steps of a method of manufacturing the power semiconductor device 100 will be described. The power semiconductor device 100 is formed through the following steps mainly, a die bonding step, a frame bonding step, a wide bonding step, a molding step, and a lead processing step.

In the die bonding step, the power semiconductor chip 1 is mounted on the heat spreader 2 using the bonding member 3.

In the frame bonding step, signal terminals such as the gate terminal 8, the anode terminal 9, and the cathode terminal 10 and structure in which main terminals such as the lead frames 5 and 7 are integrated (hereinafter referred to as “lead frame structure”), and the temperature sensing diode chip 4 are bonded to the heat spreader 2 and the power semiconductor chip 1 mounted thereon using the bonding member 6. At this point, the temperature sensing diode chip 4 is positioned so as to fit in the opening of the lead frame 5.

In the wire bonding step, wires (the gate wire 8w, the anode wire 9w, the cathode wire 10w, and the like) are ultrasonically bonded to the signal terminals (the gate terminal 8, the anode terminal 9, the cathode terminal 10, and the like) and the electrodes of the power semiconductor chip 1 and the temperature sensing diode chip 4 (the surface electrode 1a, the gate pad 1b, the cathode pad 1c, the anode electrode 4a, and the like).

In the molding step, first, the power semiconductor chip 1, the heat spreaders 2, the temperature sensing diode chip 4, the lead frame structure, and the like that have undergone the die bonding step, the frame bonding step, and the wide bonding step are set in a mold cavity together with the insulating sheet 11 provided with the metal foil 12, and the resin pellets are set in a pot. Then, after the mold is heated to a high temperature, the molten resin is extruded from the pot with a plunger and poured into the cavity from the gate of the mold through a runner, and the resin is cured at a high temperature, thereby forming the mold resin 13.

In the lead processing step, the power semiconductor device 100 after the molding step is removed from the mold, subjected to gate cutting, and unnecessary parts such as tie bars and frames from the lead frame structure are cut by pressing, thereby forming the main terminals (the lead frames 7, 8) and the signal terminals (the gate terminal 8, the anode terminal 9, the cathode terminal 10) of the power semiconductor device 100. And, the main terminals and the signal terminals are bent into a prescribed shape to complete the power semiconductor device 100.

Next, the operation of the power semiconductor device 100 will be described. When a voltage equal to or higher than a threshold is applied between the gate terminal 8 and the lead frame 7 of the power semiconductor device 100, the voltage is applied between the gate and the emitter of the power semiconductor chip 1, which is an IGBT, which turns on the power semiconductor chip 1, and a current flows through the lead frame 5, the heat spreader 2, the power semiconductor chip 1, and the lead frame 7. The power semiconductor chip 1 generates heat due to an internal resistance component when a current flows.

The temperature sensing diode chip 4 measures the temperature of the power semiconductor chip 1 in order to prevent the power semiconductor chip 1 from being broken by the heat generation. The temperature of the power semiconductor chip 1 is calculated from the voltage between the anode and the cathode of the temperature sensing diode chip 4, that is, the voltage between the anode terminal 9 and the cathode terminal 10 of the power semiconductor device 100.

Although it is possible to incorporate a temperature sensing diode inside the power semiconductor chip 1, having a separate chip of a temperature sensing diode (the temperature sensing diode chip 4) from the power semiconductor chip 1 allows the chip size of the power semiconductor chip 1 to be smaller, and this exhibits larger cost reduction effect when the power semiconductor chip 1 is formed using SiC, which is more expensive than Si. Furthermore, bonding the temperature sensing diode chip 4 in the vicinity of the center of the surface electrode 1a of the power semiconductor chip 1 allows the temperature sensing diode to be arranged within the operational region of the power semiconductor chip 1, enabling direct measurement of the temperature of the power semiconductor chip 1.

Conventionally, when the temperature sensing diode chip 4 is mounted in the central portion of the surface electrode 1a of the power semiconductor chip 1 and the lead frame 5 is to be bonded to the surface electrode 1a, insulation between the temperature sensing diode chip 4 and the lead frame 5 was difficult to secure. However, in the power semiconductor device 100 according to Embodiment 1, the side surfaces of the lead frame 5 facing temperature sensing diode chip 4 are coated with the insulating film 5a, securing insulation between the lead frame 5 and the temperature sensing diode chip 4.

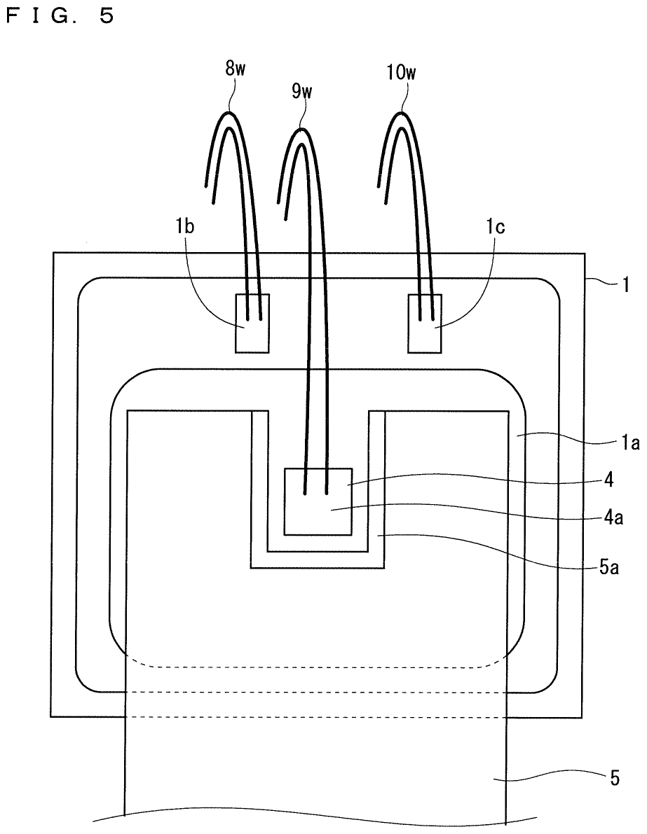

Although FIGS. 3 and 4 illustrate the configuration in which the lead frame 5 has an opening in the region where the temperature sensing diode chip 4 is arranged (first region), the shape of the lead frame 5 is not limited thereto. For example, as illustrated in FIG. 5, the lead frame 5 may have a U-shaped portion in which a notch (slit) is formed in the region where the temperature sensing diode chip 4 is arranged. The temperature sensing diode chip 4 is arranged within the U-shaped portion of the lead frame 5, surrounded by the three sides thereof. Also in this case, coating the side surfaces of the lead frame 5 facing the temperature sensing diode chip 4, that is, the side walls of the notch of the U-shaped portion with the insulating film 5a secures insulation between the lead frame 5 and the temperature sensing diode chip 4.

### Embodiment 2

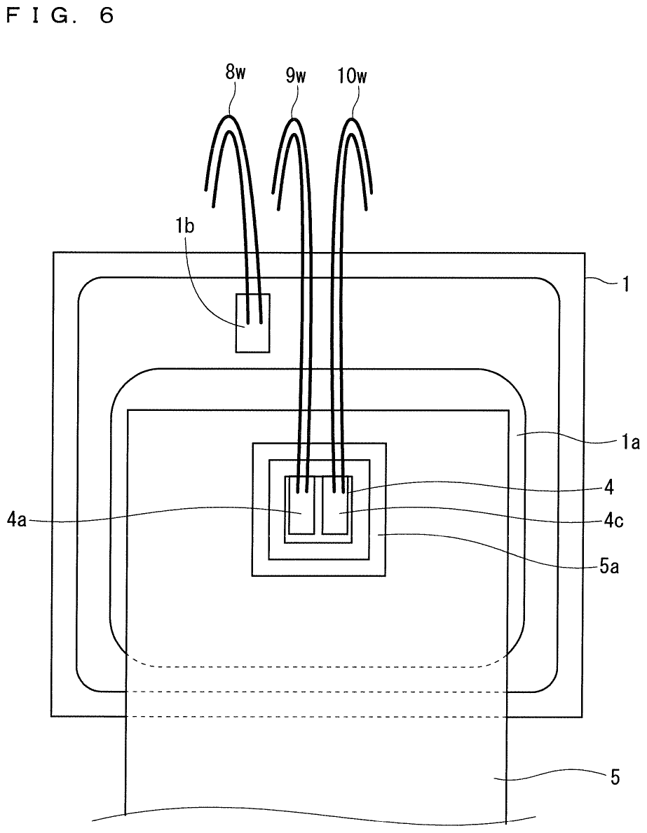

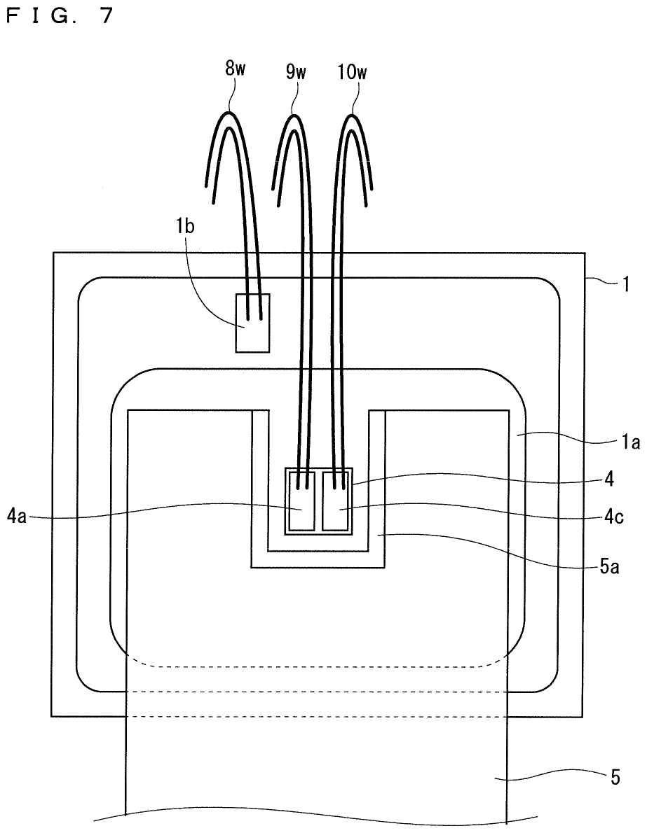

FIGS. 6 and 7 are top views of an essential part (in the vicinity of the power semiconductor chip 1) of a power semiconductor device 100 according to Embodiment 2. FIG. 6 illustrates a configuration example in which the lead frame 5 has an opening in a region where the temperature sensing diode chip 4 is arranged (first region), and FIG. 7 illustrates a configuration example in which the lead frame 5 has a U-shaped portion in which a notch (slit) is formed in the region where the temperature sensing diode chip 4 is arranged. FIGS. 6 and 7 are the same except that the shape of the lead frame 5 is different.

In embodiment 2, both the anode electrode 4a and the cathode electrode 4c are provided on the upper surface of the temperature sensing diode chip 4. The anode electrode 4a is connected to the anode terminal 9 of the power semiconductor device 100 through the anode wire 9w, and the cathode electrode 4c is connected to the cathode terminal 10 of the power semiconductor device 100 through the cathode wire 10w.

In Embodiment 1, the cathode electrode is arranged on the lower surface of the temperature sensing diode chip 4 and is shared with the emitter electrode of the power semiconductor chip 1, where the cathode potential of the temperature sensing diode chip 4 fluctuates along with the emitter potential of the power semiconductor chip 1, causing a concern that the potential fluctuations may affect measurement results of temperature. In contrast, in Embodiment 2, the cathode electrode 4c of the temperature sensing diode chip 4 is provided independently of the emitter electrode of the power semiconductor chip 1; therefore, less effect of potential fluctuations due to energization of the power semiconductor chip 1 is exerted, allowing the temperature sensing diode chip 4 to measure the temperature of the power semiconductor chip 1 more accurately.

### Embodiment 3

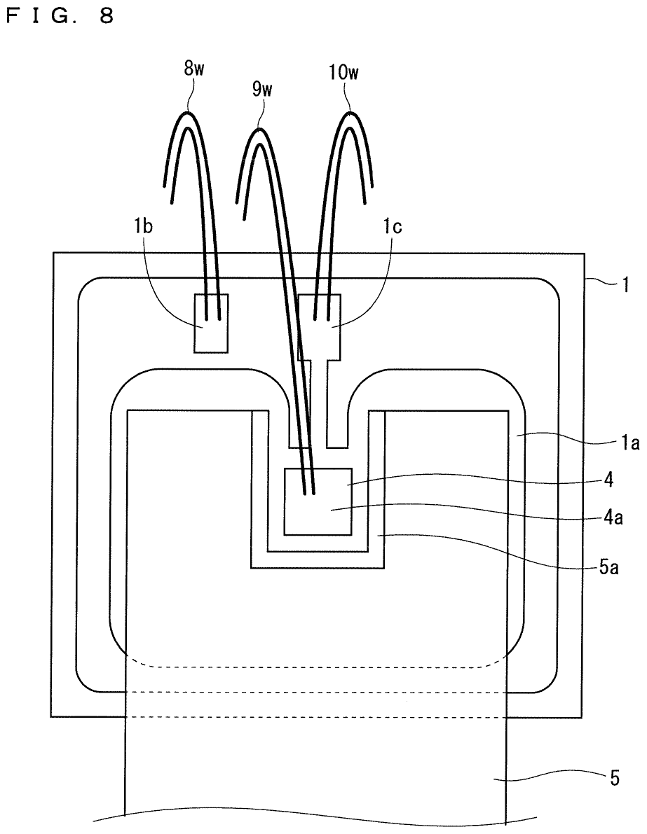

FIG. 8 is a top view of an essential part (in the vicinity of the power semiconductor chip 1) of a power semiconductor device 100 according to Embodiment 3. In FIG. 8, the lead frame 5 has a U-shaped portion in which a notch (slit) is formed in the region where the temperature sensing diode chip 4 is arranged.

As in Embodiment 1, the cathode electrode of the temperature sensing diode chip 4 is arranged on the lower surface of the chip and is bonded to the surface electrode 1a of the power semiconductor chip 1, with the cathode electrode being shared with the emitter electrode of the power semiconductor chip 1. In Embodiment 3, as illustrated in FIG. 8, a cathode pad 1c to which a cathode wire 10w is bonded is provided as a third region on a portion of the surface electrode 1a. Therefore, in the surface electrode 1a, a region to which the lead frame 5 is bonded (second region) is not interposed between the cathode pad 1c to which the cathode wire 10w is bonded (third region) and the region to which the temperature sensing diode chip 4 is bonded (first region). Therefore, the potential of the cathode wire 10w is less likely to be affected by potential fluctuations due to energization of the power semiconductor chip 1; therefore, as in Embodiment 2, the temperature sensing diode chip 4 is allowed to measure the temperature of the power semiconductor chip 1 more accurately.

Although FIG. 8 illustrates the configuration example in which the lead frame 5 has a U-shaped portion, in Embodiment 3, a configuration is also applicable where the lead frame 5 has an opening in the region in which the temperature sensing diode chip 4 is arranged (first region), and in this case, both the first region and the third region may be arranged within the opening.

### Embodiment 4

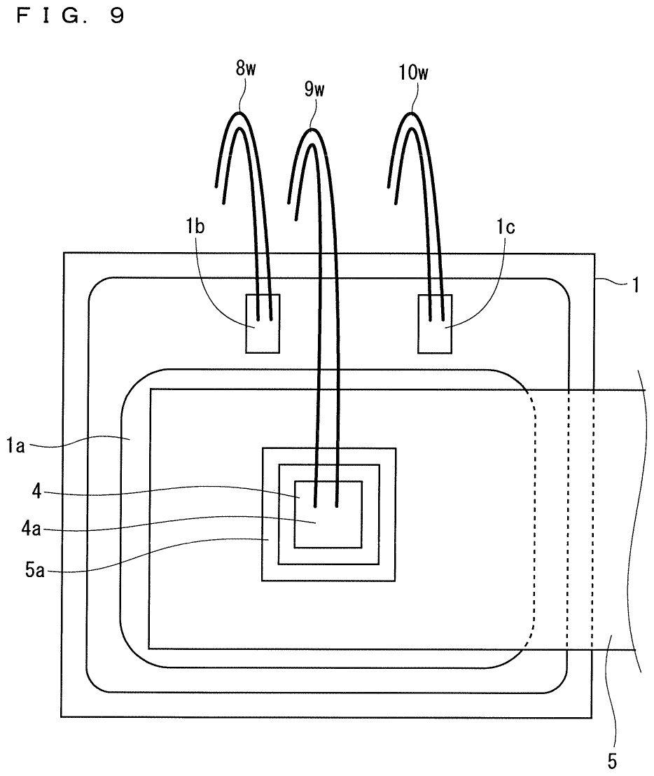

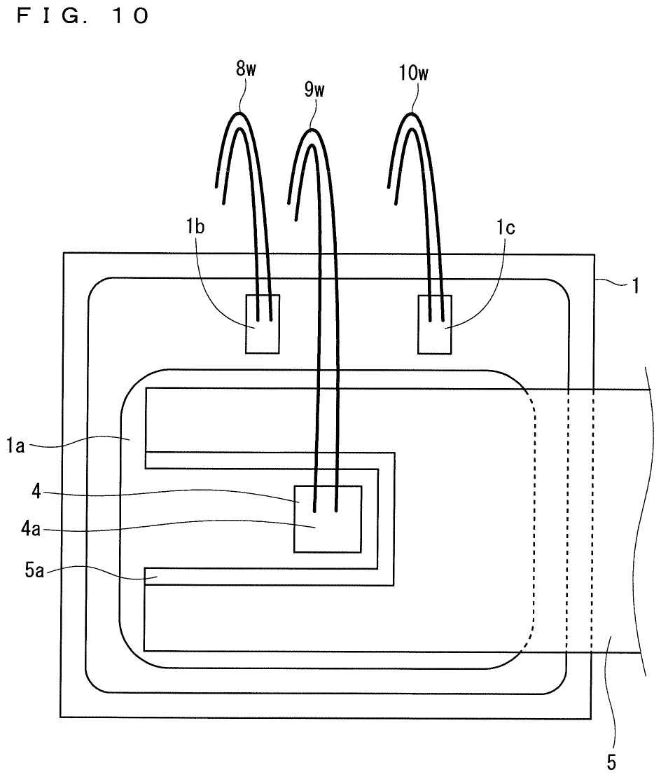

FIGS. 9 and 10 are top views of an essential part (in the vicinity of the power semiconductor chip 1) of a power semiconductor device 100 according to Embodiment 4. FIG. 9 illustrates a configuration example in which the lead frame 5 has an opening in a region where the temperature sensing diode chip 4 is arranged (first region), and FIG. 10 illustrates a configuration example in which the lead frame 5 has a U-shaped portion in which a notch (slit) is formed in the region where the temperature sensing diode chip 4 is arranged. FIGS. 9 and 10 are the same except that the shape of the lead frame 5 is different.

In Embodiment 4, the direction in which the lead frame 5 extends from the surface electrode 1a of the power semiconductor chip 1 is orthogonal to the direction in which the cathode wire 10w, which is a wire for voltage measurement of the cathode electrode of the temperature sensing diode chip 4, extends from the cathode pad 1c. In the configuration, the cathode wire 10w is less likely to be induced by the magnetic field generated when the power semiconductor chip 1 is switched between on (energization) and off (non-energization), allowing the temperature sensing diode chip 4 to measure the temperature of the power semiconductor chip 1 more accurately.

### Embodiment 5

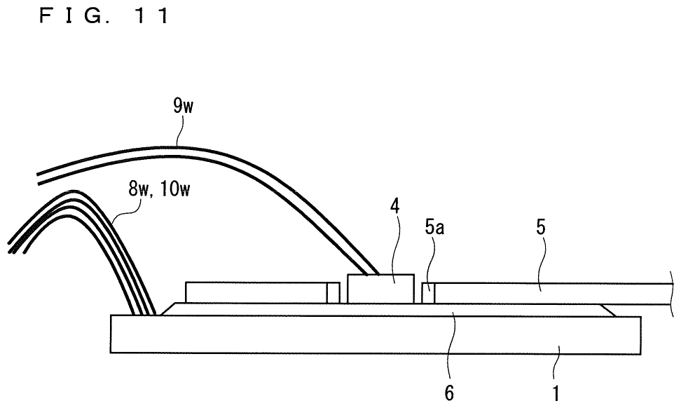

FIGS. 11, 12, and 13 are cross-sectional views of an essential part (in the vicinity of the power semiconductor chip 1) of a power semiconductor device 100 according to Embodiment 5. FIGS. 11, 12, and 13 are the same except that the shape of the lead frame 5 is different. Although these drawings illustrate a configuration example in which the lead frame 5 has an opening in a region where the temperature sensing diode chip 4 is arranged (first region), a configuration in which the lead frame 5 has a U-shaped portion in which a notch (slit) is formed in the region where the temperature sensing diode chip 4 is arranged may also be adoptable.

In Embodiment 5, the lead frame 5 is configured such that the upper surface of the lead frame 5 is lower than the upper surface of temperature sensing diode chip 4 at least in the portion facing the temperature sensing diode chip 4.

FIG. 11 illustrates an example in which the overall thickness of lead frame 5 is reduced so that the height of the upper surface of lead frame 5 is lower than the height of the upper surface of temperature sensing diode chip 4. The lead frame 5 can be formed by processing the lead frame 5 using a metal plate (such as a copper plate) thinner than the temperature sensing diode chip 4.

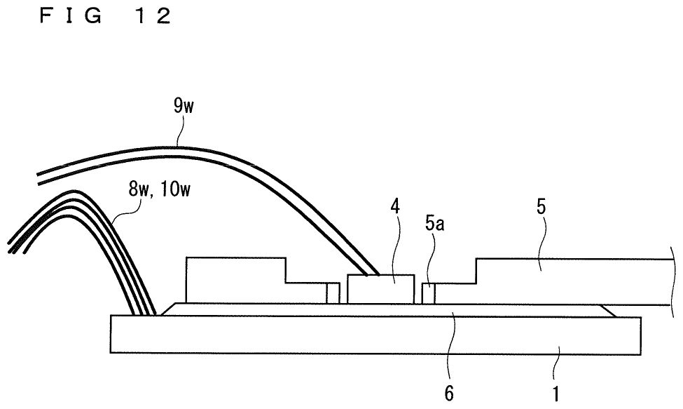

FIG. 12 illustrates an example in which a step is provided on the upper surface of the lead frame 5 so that the portion of the lead frame 5 facing the temperature sensing diode chip 4 is lower than the upper surface of the temperature sensing diode chip 4. The lead frame 5 can be formed by crushing the portion of the lead frame 5 facing the temperature sensing diode chip 4 to make the thickness of that portion thinner than the thickness of the temperature sensing diode chip 4.

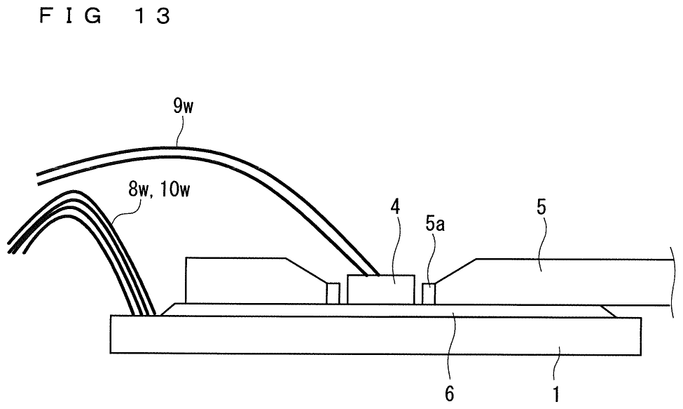

FIG. 13 is an example in which the upper surface of the portion of the lead frame 5 facing the temperature sensing diode chip 4 is inclined so that the lead frame 5 is lower on the end portion side of the lead frame 5, thereby making the portion of the lead frame 5 facing the temperature sensing diode chip 4 lower than the upper surface of the temperature sensing diode chip 4. The lead frame 5 can be formed by chamfering a portion of the lead frame 5 facing the temperature sensing diode chip 4 and making the chamfered portion thinner than the thickness of the temperature sensing diode chip 4.

In Embodiment 5, the upper surface of the temperature sensing diode chip 4 is higher than the upper surface of the portion of the lead frame 5 facing the temperature sensing diode chip 4; therefore, the step of mounting the temperature sensing diode chip 4 on the surface electrode 1a of the power semiconductor chip 1 at the same time as the lead frame 5 is facilitated. In addition, when the anode wire 9w is bonded to the anode electrode 4a on the upper surface of the temperature sensing diode chip 4, an effect of preventing the bonding tool from interfering with the lead frame 5 can be obtained.

Further, formation of the lead frame 5 in FIG. 11 requires the use of a metal plate thinner than that of the temperature sensing diode chip 4, whereas the lead frame 5 of FIGS. 12 and 13 can also be formed from a metal plate thicker than that of the temperature sensing diode chip 4, and this has an advantage that there is a wider range of choice of materials for the lead frame 5.

### Embodiment 6

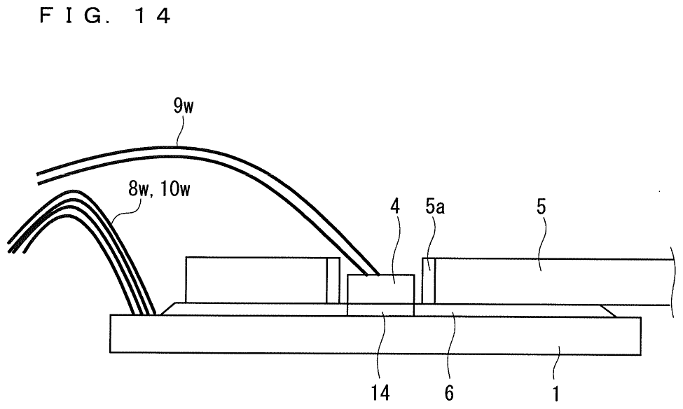

FIGS. 14 and 4 is a cross-sectional view of an essential part (in the vicinity of the power semiconductor chip 1) of a power semiconductor device 100 according to Embodiment 6. FIG. 14 illustrates a configuration example in which the lead frame 5 has an opening in a region where the temperature sensing diode chip 4 is arranged (first region), a configuration in which the lead frame 5 has a U-shaped portion in which a notch (slit) is formed in the region where the temperature sensing diode chip 4 is arranged may also be adoptable.

In the power semiconductor device 100 of Embodiment 6, although the lead frame 5 is bonded to the surface electrode 1a of the power semiconductor chip 1 using the bonding member 6 made of solder, whereas the temperature sensing diode chip 4 is bonded to the surface electrode 1a of the power semiconductor chip 1 using an Ag bonding member 14 made of silver (aG).

Comparing to solder, the Ag bonding member 14 has a lower thermal resistance and less void generation; therefore, according to Embodiment 6, the heat of the power semiconductor chip 1 is efficiently transmitted to the temperature sensing diode chip 4, which allows the temperature sensing diode chip 4 to measure the temperature of the power semiconductor chip 1 more accurately.

The Embodiments can be combined, appropriately modified or omitted.

The foregoing description is in all aspects illustrative and not restrictive, and it is therefore understood that numerous modifications can be devised.

### EXPLANATION OF REFERENCE SIGNS

100 power semiconductor device, 1 power semiconductor chip, 1a surface electrode, 1b gate pad, 1c cathode pad, 2 heat spreader, 3 bonding member, 4 temperature sensing diode chip, 4a anode electrode, 4c cathode electrode, 5 lead frame, 5a insulating film, 6 bonding member, 7 lead frame, 8 gate terminal, 8w gate wire, 9 anode terminal, 9w anode wire, 10 cathode terminal, 10w cathode wire, 11 insulating sheet, 12 metal foil, 13 mold resin, 14 Ag bonding member.

1. A power semiconductor device comprising:
a power semiconductor chip being a chip of a power semiconductor element;
a temperature sensing diode chip being a chip of a temperature sensing diode element mounted in a first region on a surface electrode being one of main electrodes of the power semiconductor chip;
a lead frame connected to a second region on the surface electrode; and
an insulating film provided on a side surface of the lead frame facing the temperature sensing diode chip.

2. The power semiconductor device according to claim 1, wherein
the temperature sensing diode chip is mounted on a central portion of the surface electrode.

3. The power semiconductor device according to claim 1, wherein
the lead frame has an opening, and
the temperature sensing diode chip is arranged within the opening of the lead frame.

4. The power semiconductor device according to claim 1, wherein
the lead frame has a U-shaped portion, and
the temperature sensing diode chip is arranged within the U-shaped portion of the lead frame, surrounded by three sides thereof.

5. The power semiconductor device according to claim 1, wherein
the temperature sensing diode chip is provided with both an anode electrode and a cathode electrode on an upper surface thereof.

6. The power semiconductor device according to claim 1, wherein
the temperature sensing diode chip is provided with a cathode electrode connected to the surface electrode on a lower surface thereof,
a wire for voltage measurement of the cathode electrode is connected to a third region on the surface electrode, and
the second region is not interposed between the third region and the first region.

7. The power semiconductor device according to claim 1, wherein
the temperature sensing diode chip is provided with a cathode electrode connected to the surface electrode on a lower surface thereof, and
a direction in which the lead frame extends from the surface electrode is orthogonal to a direction in which the wire for voltage measurement of the cathode electrode extends.

8. The power semiconductor device according to claim 1, wherein,
at least in a portion of the lead frame facing the temperature sensing diode chip, a height of an upper surface of the lead frame is lower than a height of the upper surface of the temperature sensing diode chip.

9. The power semiconductor device according to claim 8, wherein
the upper surface of the lead frame has a step so that the portion facing the temperature sensing diode chip is lowered.

10. The power semiconductor device according to claim 8, wherein
at least an upper surface of the portion of the lead frame facing the temperature sensing diode chip is inclined so that the lead frame is lower on an end portion side thereof.

11. The power semiconductor device according to claim 1, wherein
the temperature sensing diode chip is bonded to the surface electrode using silver, and
the lead frame is bonded to the surface electrode using solder.
